(19) United States
(12) Patent Application Publication
(10) Pub. No.: US 2013/0298987 A1
(43) Pub. Date: Nov. 14, 2013

(54) METHOD FOR MANUFACTURING A MULTILAYER OF A TRANSPARENT CONDUCTIVE OXIDE

(71) Applicants: Paolo Losio, Pfaffikon (CH); Onur Caglar, Thalwil (CH); Peter Rechtsteiner, Mels (CH); Perrine Carroy, Chur (CH); Holger Christ, Azmoos (CH)

(72) Inventors: Paolo Losio, Pfaffikon (CH); Onur Caglar, Thalwil (CH); Peter Rechtsteiner, Mels (CH); Perrine Carroy, Chur (CH); Holger Christ, Azmoos (CH)

(73) Assignee: TEL SOLAR AG, Trubbach (CH)

(21) Appl. No.: 13/979,794

(22) PCT Filed: Jan. 13, 2012
(86) PCT No.: PCT/EP2012/050479

§ 371 Date: Jul. 15, 2013

Related U.S. Application Data
(60) Provisional application No. 61/434,022, filed on Jan. 19, 2011.
(60) Provisional application No. 61/512,074, filed on Jul. 27, 2011.

(51) Int. Cl. H01L 31/0224; H01L 31/18

(52) U.S. Cl. CPC H01L 31/022483; H01L 31/1884
USPC 136/256; 438/98

(57) ABSTRACT

A multi-part transparent conductive zinc oxide layer for a photoelectric conversion device, and a method of producing same. The transparent conductive zinc oxide layer includes at least one basic layer sequence with a varying boron dopant concentration. The basic layer sequence includes a thinner transparent conductive zinc oxide higher-boron-doped layer and a thicker transparent conductive zinc oxide lower-boron-doped layer. The doping density through each individual conductive zinc oxide layer is substantially constant, which is achieved by intentionally doping the thicker transparent conductive zinc oxide lower-boron-doped layer. Optionally, an interlayer may be present between the at least one basic layer sequence and the substrate or an n-doped silicon layer upon which it is disposed. This advantageously permits efficient Edge Isolation by Laser EIL ablation of the transparent conductive zinc oxide layers while maintaining good electrical and optical properties in said layers.

### FIELD OF THE INVENTION

Photovoltaic devices or solar cells are devices which convert light into electrical power. Thin film solar cells nowadays are of a particular importance since they have a huge potential for mass production at low cost. This disclosure addresses issues in the production of ZnO front and back contacts to enhance Edge Isolation by Laser (EIL) processes and improve module power.

### DEFINITIONS

Processing in the sense of this invention includes any chemical, physical or mechanical effect acting on substrates.

Substrates in the sense of this invention are components, parts or workpieces to be treated in a processing apparatus. Substrates include but are not limited to flat, plate shaped parts having rectangular, square or circular shape. In a preferred embodiment this invention addresses essentially planar substrates of a size >1 m², such as thin glass plates.

A vacuum processing or vacuum treatment system or apparatus comprises at least an enclosure for substrates to be treated under pressures lower than ambient atmospheric pressure.

CVD Chemical Vapour Deposition is a well-known technology allowing the deposition of layers on heated substrates. A usually liquid or gaseous precursor material is fed to a process system where a thermal reaction of said precursor results in deposition of said layer. LPCVD is a common term for low pressure CVD.

DEZ—diethyl zinc is a precursor material for the production of TCO layers in vacuum processing equipment.

TCO stands for transparent conductive oxide, TCO layers consequently are transparent conductive layers.

The terms layer, coating, deposit and film are interchangeably used in this disclosure for a film deposited in vacuum processing equipment, be it CVD, LPCVD, plasma enhanced CVD (PECVD) or PVD (physical vapour deposition)

A solar cell or photovoltaic cell (PV cell) is an electrical component, capable of transforming light (essentially sun light) directly into electrical energy by means of the photoelectric effect.

A thin-film solar cell in a generic sense includes, on a supporting substrate, at least one p-i-n junction established by a thin film deposition of semiconductor compounds, sandwiched between two electrodes or electrode layers. A p-i-n junction or thin-film photoelectric conversion unit includes an intrinsic semiconductor compound layer sandwiched between a p-doped and an n-doped semiconductor compound layer. The term intrinsic is to be understood as not intentionally doped.

The term thin-film indicates that the layers mentioned are deposited as thin layers or films by processes like, PEVCD, CVD, PVD or alike. Thin layers essentially mean layers with a thickness of 10 μm or less, especially less than 2 μm.

### BACKGROUND OF THE INVENTION

FIG. 1 shows a tandem-junction silicon thin film solar cell as known in the art. Such a thin-film solar cell 50 usually includes a first or front electrode 42, one or more semiconductor thin-film p-i-n junctions (52-54, 51, 44-46, 43), and a second or back electrode 47, which are successively stacked on a substrate 41. Each p-i-n junction 51, 43 or thin-film photoelectric conversion unit includes an i-type layer 53, 45 sandwiched between a p-type layer 52, 44 and an n-type layer 54, 46 (p-type=positively doped, n-type=negatively doped). Substantially intrinsic in this context is understood as not intentionally doped or exhibiting essentially no resultant doping. Photoelectric conversion occurs primarily in this i-type layer; it is therefore also called absorber layer.

Depending on the crystalline fraction (crystallinity) of the i-type layer 53, 45 solar cells or photoelectric (conversion) devices are characterized as amorphous (a-Si, 53) or microcrystalline (pc-Si, 45) solar cells, independent of the kind of crystallinity of the adjacent p and n-layers. Microcrystalline layers are understood, as common in the art, as layers comprising of a significant fraction of crystalline silicon—so called micro-crystallites—in an amorphous matrix. Stacks of p-i-n junctions are called tandem or triple junction photovoltaic cells. The combination of an amorphous and micro-crystalline p-i-n-junction, as shown in FIG. 1, is also called micromorph tandem cell.

### DRAWBACKS KNOWN IN THE ART

Processes used in the production of commercial thin film silicon photovoltaic modules should maximize module power and at the same time minimize production costs.

The production of thin film silicon modules involves several steps. Normally, as a first step a TCO layer is applied as front electrode 42 and subsequently silicon layers (52-54) on a glass substrate 41 (or comparable materials). This coating step affects the whole surface of a panel 61 (FIG. 2). This panel 61 however includes an active area 62 with the photovoltaically active layers with cells 63 electrically connected in series and/or parallel. To ensure electrical insulation, the edge area 64 of each module or panel 61 needs to be cleaned of all TCO and Silicon layers. After this step modules can be laminated to protect them from weathering. The edge area thus provides a barrier for environmental influences to negatively affect the sensitive active cells 63 in the active area 62.

In other words, appropriate electrical insulation to a surrounding frame or housing of a finished solar module is necessary. Therefore, the edge isolation process plays a key role to assure compliance with safety rules and to reduce the penetration of moisture into the active layers after lamination.

One approach to edge isolation involves mechanical removal of the layers in the edge area 64 by using abrasives, e.g. by sandblasting or similar techniques. The main disadvantage is a damage of the substrate surface (micro cracks, roughening).

Alternatively, TCO and Silicon layers can be removed by using a laser beam. A process based on laser application has several advantages:
No damaging or weakening of the substrate surface. (processing of surface is more gentle)
Edge Isolation by Laser (EIL) Process can be used through the substrate/glass (TTG).
A laser beam TTG will not be disturbed by ablated particles and plasma phenomena.
No additional consumption of abrasive materials (e.g. corundum) is needed.

The EIL process works by removing (ablation and/or vaporization) the silicon and ZnO layers due to absorption of Laser energy in the layers.

Further details of an EIL process have been described in U.S. Provisional Patent Application for “METHOD AND DEVICE FOR ABALATION OF THIN FILMS FROM A SUBSTRATE”, Ser. No. 61/262,691 which is incorporated herein by reference.

The performance of thin film silicon modules is strongly influenced by the properties of the first TCO layer(s) (front contact 42, FIG. 1). Relevant properties of the TCO to be considered are total transmission, haze and conductivity.

In common TCO based on LPCVD ZnO these three parameters can be varied by modifying the amount of dopant gas (usually diborane, B₂H₆) added to the precursor gases during growth in a LPCVD process. When the complete layer is made using one single set of gas flows and the layers thickness is kept constant, it is known in the art:
Increasing the doping amount reduces haze, reduces total transmission of red and NIR light and increases conductivity.
Decreasing the doping amount leads to the inverse effects.

Best module performance is obtained by increasing total transmission, increasing haze and increasing conductivity: obviously it is not possible to achieve all these goals in a single layer system.

A common tradeoff to improve module performance is therefore to reduce the doping level of TCO to improve total transmission and haze by accepting a certain loss of conductivity. If the doping is reduced too much, module performance will drop due to ohmic losses in the TCO layer. However, the EIL process requires a minimal amount of doping to work properly. A higher doping of TCO front contact improves the removal of thin film layers and allows enhancing the EIL process. Again, if the doping is too high, module performance drops due to high absorption of light (VIS, NIR) and low haze in the TCO layer.

In order to address this issue the document GROWTH OF LPCVD ZnO BILAYERS FOR SOLAR CELL FRONT ELECTRODES, AUTHORED BY L. Ding at al., presented at the 25^{th} EU-PVSEC in September 2010 in Valencia, suggests using TCO-ZnO bilayers, consisting in the combination of a highly doped plus a non-intentionally doped part, deposited in one growth step. However, according to experiments, this particular arrangement of bilayers, specifically the non-intentionally doped portion, does not adequately balance the competing requirements as outlined above.

### SUMMARY OF THE INVENTION

The present invention thus seeks to overcome the drawbacks in the prior art, and thereby provide a TCO-ZnO electrode providing good module performance while also allowing enhanced removal of the front electrode by the EIL process. This is achieved by the characteristics of the independent claims 1 and 11.

Specifically, this is achieved by an electrode for a photoelectric conversion device comprising at least one basic layer sequence with varying boron dopant concentration, said basic layer sequence comprising a thinner transparent conductive zinc oxide higher-boron-doped layer and a thicker transparent conductive zinc oxide lower-boron-doped layer wherein the doping density through each individual conductive zinc oxide layer is substantially constant. Such a multi-part, bilayer structure enables the thinner, high-doped layer to be sufficiently doped to absorb laser light in the EIL process and thus be easily ablated while not adversely affecting the optical and/or electrical performance of the photoelectric conversion device, and the electrical and optical properties of the thicker, low-doped layer to be optimised for light transmission and electrical conductivity without negatively affecting the performance of the EIL process. In this case, “thinner”, “thicker”, “higher” and “lower” have their usual meanings, i.e. the “thinner” layer has a lower thickness than the “thicker” layer, and the “higher”-doped layer has a higher doping concentration than the “lower”-doped layer. In addition, “substantially constant” signifies that the doping density is broadly constant throughout the majority of the thickness of each layer. It is perfectly known by the skilled person that, due to processing artefacts, dopant diffusion and similar phenomena, there may be a doping density gradient present at the junction of the two layers in a relatively thin portion of the thickness of either or both layers, which is to be construed as falling within the scope of the invention and the claims.

In an embodiment, the electrode may comprise a plurality of said basic layer sequences, i.e. a sequence of high-doped, low-doped, high-doped, low-doped etc. This enables simple and efficient production of a front electrode having the desired properties on existing production equipment without substantial modification thereto.

In an embodiment, the electrode is a front electrode and is arranged on a preferably glass substrate so that it can be formed into a solar panel or a solar cell.

In an embodiment, an interlayer is disposed between the at least one basic layer sequence and the substrate. This enables better adhesion between the basic layer sequence and the substrate without affecting the performance of the photoelectric conversion device and the EIL process. Alternatively, the least one basic layer sequence is arranged in direct and intimate contact with the substrate. This brings the easily-ablated higher-doped layer closer to the substrate, which enables better removal of the TCO-ZnO layer from the substrate.

In an embodiment, the electrode is a back electrode and is arranged on a n-doped silicon layer, permitting use of the inventive electrode structure as a back electrode.

In an embodiment, an interlayer is disposed between the at least one basic layer sequence and the n-doped layer. This enables better adhesion between the basic layer sequence and the n-doped layer without affecting the performance of the photoelectric conversion device and the EIL process. Alternatively, the at least one basic layer sequence is arranged in direct and intimate contact with the n-doped silicon layer, permitting a simple construction of the back eletrode.

In an embodiment, the doping concentration of the interlayer (76) is lower than that of the said thinner transparent conductive zinc oxide higher-boron-doped layer, assisting in the adhesion between the substrate or n-doped layer and the adjacent layer.

Furthermore, the aim of the invention is achieved by a method for manufacturing an electrode for a photoelectric conversion device comprising depositing on a substrate or on a n-doped silicon layer at least one basic layer sequence with varying boron dopant concentration, the said basic layer sequence comprising a thinner transparent conductive zinc oxide higher-boron-doped layer and a thicker transparent conductive zinc oxide lower-boron-doped layer, wherein the thicker transparent conductive zinc oxide lower-boron-doped layer is intentionally doped, that is to say is actively subjected to a dopant-containing environment during its deposition rather than being doped purely by diffusion or contamination. This intentional doping creates the substantially constant doping density of the lower-doped layer, and thereby enables the optimisation of the doping levels, so as to achieve the desired electrical and optical properties of the layer and of the front electrode as a whole.

In an embodiment, the method further comprises a step of depositing an interlayer between the substrate or the n-doped silicon layer as appropriate and the at least one basic layer sequence. This enables better adhesion between the basic layer sequence and the substrate or the n-doped layer without affecting the performance of the photo-electric conversion device and the EIL process.

In an embodiment, the method comprises depositing the basic layer sequence in the steps of depositing on the substrate or the n-doped silicon layer as appropriate a first transparent conductive zinc oxide layer, then depositing on this first transparent conductive zinc oxide layer a second transparent conductive zinc oxide layer, wherein the first conductive zinc oxide layer is either the thinner transparent conductive zinc oxide higher-boron-doped layer or the thicker transparent conductive zinc oxide lower-boron-doped layer and the second transparent conductive zinc oxide layer is the other of the thinner transparent conductive zinc oxide higher-boron-doped layer or the thicker transparent conductive zinc oxide lower-boron-doped layer, i.e. the deposition order is either higher-doped—lower-doped, or lower-doped—higher-doped. This thus provides for the deposition of the transparent conductive zinc oxide layers in the desired sequence.

In an embodiment, an interlayer can be deposited on the substrate or the n-doped silicon layer as appropriate, followed by the order of transparent conductive zinc oxide layers as described in the previous paragraph. This enables the interlayer followed by the desired sequence of transparent conductive zinc oxide layers to be deposited.

In an embodiment, the first conductive zinc oxide layer is the thinner transparent conductive zinc oxide higher-boron-doped layer and the second conductive zinc oxide layer is the thicker transparent conductive zinc oxide lower-boron-doped layer. This has the advantage of placing the higher-doped layer directly adjacent to the substrate, n-doped layer or interlayer as appropriate, thus bringing the higher-doped layer which is most susceptible to the EIL process, closer to the substrate, n-doped layer or interlayer, thus enhancing of the conductive zinc oxide layer, particularly in the case of a front electrode with the TCO layer directly on the substrate, when the laser absorption in the EIL process will be directly adjacent to the substrate and the ablation of the TCO layer will thus be maximised. In the case of a back electrode, having the higher-doped TCO layer directly adjacent to the silicon n-layer improves the electrical contact between the solar cell and the TCO electrode.

In an embodiment, the layers are deposited by means of a vacuum processing method such as Chemical Vapour Deposition (CVD), Low Pressure Chemical Vapour Deposition (LPCVD), Plasma Enhanced Chemical Vapour Deposition (PECVD), or Physical Vapour Deposition (PVD). The choice of any of these processes enables efficient, economic deposition of the layers.

In an embodiment, the thinner, higher-doped layer is deposited under conditions of the first B₂H₆/DEZ ratio of 0.1-1, preferably 0.2-0.55. This enables the desired doping properties of the thinner layer to be attained.

In an embodiment, the thicker, lower-doped layer is deposited under conditions of a second B₂H₆/DEZ ratio of 0.01-0.2, preferably 0.02-0.1. This enables the desired doping properties of the thicker layer to be attained.

In an embodiment, the ratio of the first to second B₂H₆/DEZ ratios is between 2 and 60, preferably between 7 and 10, further preferably between 7 and 8. This enables the desired doping properties of the thicker layer to be attained.

In an embodiment, both transparent zinc oxide layers are deposited under conditions of a H2O/DEZ ratio of 0.8 to 1.5.

In an embodiment, the deposition is carried out on a substrate with a temperature of 150-220° C., preferably 180-195° C., which enables good adhesion of the layers to the preferably glass substrate.

In an alternative embodiment, the deposition is carried out on a substrate with a temperature of 150-260° C., preferably 205-250° C., which enables a deposition rate up to approximately 10 nm/s, thereby enabling rapid production.

In an embodiment, a plurality of basic layer sequences are deposited sequentially on the substrate by further depositing at least one further first transparent conductive zinc oxide layer and at least one further second transparent conductive zinc oxide layer, i.e. forming a sequence of high-doped, low-doped, high-doped, low-doped and so on layers. This enhances the EIL process by distributing the absorption of laser light throughout the thickness of the front electrode, leading to improved ablation, while still retaining adequate electrical and optical properties for the electrode. In addition, it also enables use of existing processing machinery to carry out the method and produce an electrode having adequate electrical and optical properties with good susceptibility to the EIL ablation process.

In an embodiment, the thinner, higher-boron-doped layer and the thicker, lower-boron-doped layer of the/each at least one basic layer sequence are deposited in two individual, separate, discrete processing steps. This enables better quality layers to be produced, particularly the thicker, lower-boron-doped layer, since by using two discrete steps there is no residual higher-concentration dopant in the deposition chamber which might affect the deposition of the lower-boron-doped layer. This additionally helps maintain the doping density through the lower-boron-doped layer substantially constant, enabling more precise control of the desired dopant concentration and thus electrical and optical properties of the layers, and minimises or eliminates any dopant density gradient at the interface between the layers.

In an alternate embodiment, the thinner transparent conductive zinc oxide higher-boron-doped layer and the thicker transparent conductive zinc oxide lower-boron-doped layer of the (or indeed each and every in the case of multiple layer sequences) at least one basic layer sequence are deposited sequentially by varying the diborane/diethyl zinc ratio from the said first diborane/diethyl zinc ratio to the said second diborane/diethyl zinc ratio or from the said second diborane/diethyl zinc ratio to the said first diborane/diethyl zinc ratio over a time period of 30 seconds or less. The ratio can be varied e.g. by varying the diborane flow as required over the desired time period. This enables faster production, while preventing any doping density gradient between the thicker and the thinner layers at their interface from becoming too pronounced.

In an embodiment, the doping concentration of the interlayer (76) is lower than that of the said thinner transparent conductive zinc oxide higher-born-doped layer, assisting in the adhesion between the substrate or n-doped layer and the adjacent layer.

Further specific embodiments and advantages are described in relation to the embodiments illustrated in the figures.

### BRIEF DESCRIPTION OF THE DRAWINGS

FIG. 1 shows a tandem junction thin-film silicon photovoltaic cell according to the prior art;

FIG. 2 shows a side view of a conventional thin-film photovoltaic panel;

FIG. 3 shows a schematic representation of the basic layer structure according to the invention;

FIG. 4 shows a schematic representation of a more complex structure with a plurality of basic layer structures according to the invention;

FIG. 5 shows a schematic representation of the basic layer structure provided on an interlayer according to a further aspect of the invention; and

FIG. 6 shows a schematic representation of a more complex structure with a plurality of basic layer structures on an interlayer according to a further aspect of the invention.

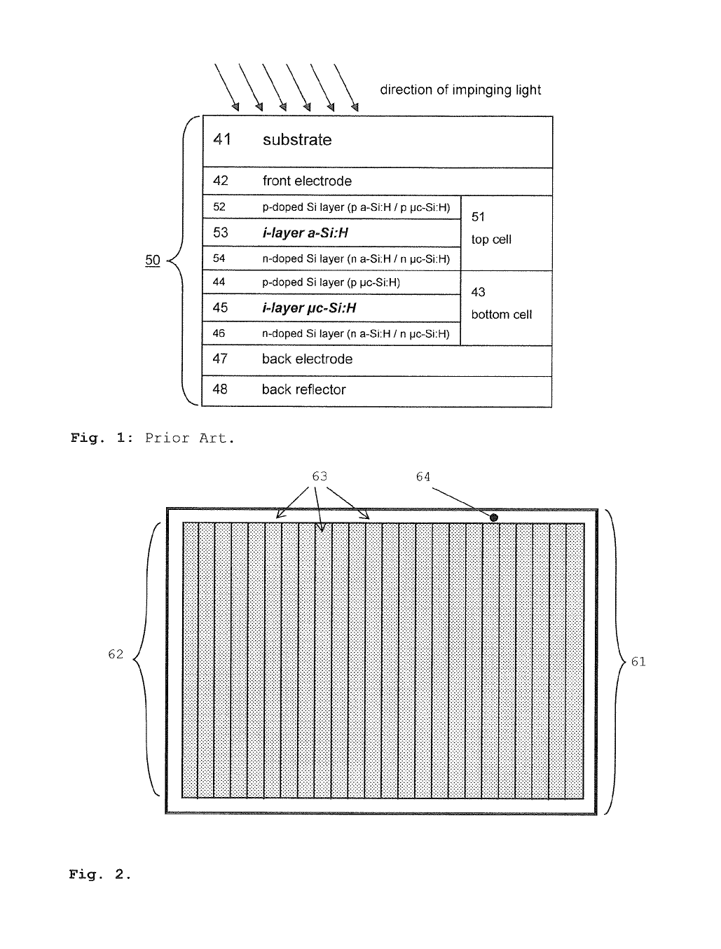

### DETAILED DESCRIPTION OF THE INVENTION

This invention is related to using a multilayer TCO system, which can be used advantageously in combination with the EIL process. In a multilayer TCO system according to the invention it is possible to use a stack of layers each with a specific function. In this case, a highly doped layer is used which is able to absorb the laser energy during an EIL process, thus enhancing removal of unwanted material. Additionally, this highly doped layer will improve the conductivity of the complete TCO stack. Subsequently, a thicker and low doped layer provides for haze and for keeping total transmission high.

The following solution is presented for simultaneously improving module performance and enhancing the EIL process.

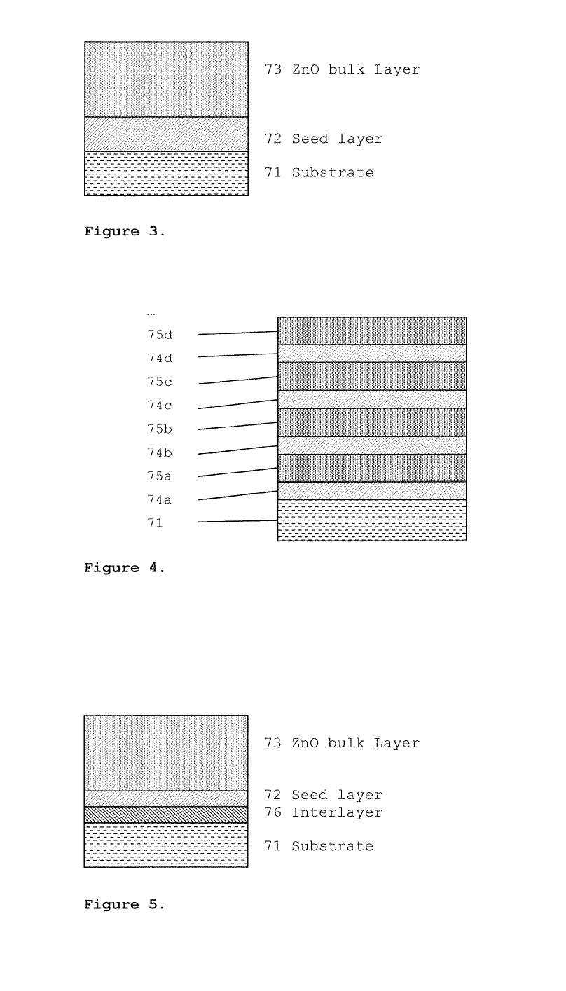

A first embodiment of a TCO Multilayer system according to the invention is described with a view on FIG. 3:

A first ZnO Layer (identified as seed layer 72) is deposited on a substrate 71, preferably glass. Said first layer is strongly doped with boron to increase the absorption in the NIR (Typically 1064 nm and 1030 nm, respectively, for an EIL system). This layer enhances conductivity and supports the EIL process.

Process parameters for realizing such an embodiment would be a B₂H₆/DEZ ratio of 0.1 to 2, preferred range 0.2 to 1; more preferred range 0.2 to 0.6. Temperature of glass: 150-220° C., preferred range 180-195° C. (for deposition rate below 4 nm/s). H₂O/DEZ ratio: 0.8 to 1.5; thickness less than 300 nm. Preferred thickness is 50 nm to 200 nm. Without deviating from the inventive concept it is possible to obtain comparable results by increasing the doping ratio while reducing layer thickness or by decreasing the doping while increasing the layer thickness. Alternatively, the temperature of the glass may be in the range 150-260° C., best range 205-250° C. (for deposition rate up to 10 nm/s).

Subsequent bulk layer 73 is deposited with process parameters as known in the art for single-layer ZnO-TCO processes:

ZnO layer 73 is lowly doped to provide haze and to keep absorption low, thus increasing the current generated in the microcrystalline cell. Process parameters for such a layer include a B₂H₆/DEZ ratio from 0.01 to 0.2, best range 0.02 to 0.1. The required minimal doping of the layer insures a reduced degradation of the conductivity upon exposure to moisture. Temperature of the glass during deposition step: 150-220° C., best range 180-195° C. (for deposition rate below 4 nm/s). H₂O/DEZ ratio: 0.8 to 1.5. Thickness from 500 nm to several micrometers, good range 900 nm to 3 um, best results with no more than 2 μm total thickness. Alternatively, the temperature of the glass may be in the range 150-260° C., best range 205-250° C. (for deposition rate up to 10 nm/s).

The two layers 72, 73 may be deposited in two completely separate steps, or they may be created by varying the diborane/diethyl zinc ratio in the process chamber over a time period of 30 seconds or less, e.g. by increasing or decreasing the diborane flow as required.

A second embodiment is shown in FIG. 5. It includes an additional layer (identified as interlayer 76 in FIG. 5) between the glass substrate 71 and the first highly doped seed layer 72. The doping of such a layer is preferably lower than the seed layer 72 doping.

A third embodiment according to the invention includes a further developed process which may be implemented in a multiple PM deposition system. Basically two approaches are possible: either a single process module PM is capable of producing a layer sequence with varying dopant addition or, in an inline system with several process modules, all PMs produce just a fraction or share of said sequence. Said fraction may be exactly the same for all PMs or varying.

A typical basic layer sequence corresponding to this third embodiment is included in FIG. 4 and involves a first highly doped layer 74a with a thickness up to 100 nm and a subsequently deposited lowly doped layer 75a with a thickness of 100-500 nm. The total thickness of a ZnO layer corresponds then to the thickness of a basic layer sequence (74a/75a) multiplied by the number of PM depositing it sequentially. In other words, layers 74b, 74c, 74d have essentially the same thickness and doping as layer 74a. Layers 75b, c, d, . . . have essentially the same thickness and doping as layer 75a.

In a variant of said process, each PM may deposit two layer sequences (74a/74b; 74b/75b; . . . ); the calculation of the resulting layer stack can be easily derived.

FIG. 4 shows such a layer stack comprising a plurality of layer sequences 74a-d/75a-d, wherein each layer sequence includes a first highly doped TCO-ZnO layer 74a-d and a subsequent second ZnO TCO layer 75a-d with low dopant concentration. The term lowly and highly doped means that the B₂H₆/DEZ ratio in the precursor materials is between 2 to 60 times higher between “low” and “high”, with preferred ratios of 7-10 times higher, especially preferred 7-8 times higher.

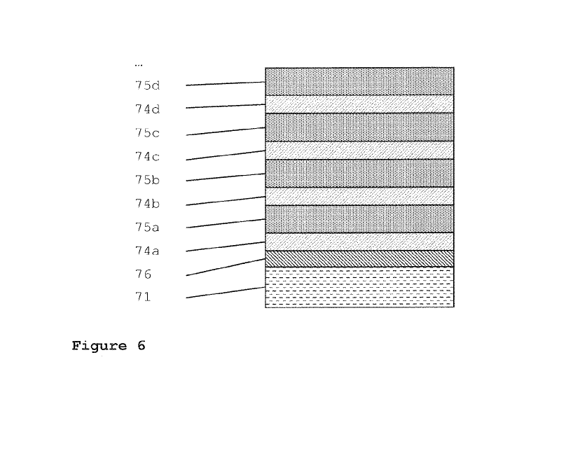

The second and third embodiment can be combined to become a fourth embodiment: On a substrate 71 an interlayer 76 is deposited, followed by a plurality of high and low doping layers 74/75. The corresponding deposition process can be performed either in a single PM that can produce a layer sequence including an interlayer or in a plurality of PM's, wherein each PM produces a fraction of the desired layer sequence. FIG. 6 shows the fourth embodiment.

All approaches have been shown to improve the EIL process compared to a layer consisting only of the lowly doped layer.

Up to now, all embodiments have been described as front contacts or front electrodes 42. However, all the presented approaches can be used to produce back contacts, too. In this case, for use as a back electrode layer 47 as shown, the n-doped layer 46 “replaces” substrate 71 in the respective Figures. The deposition sequence is kept the same in order to be able to use the same types of machines to produce both front and back contacts.

By using another type of machine, the deposition sequence could be inverted (lowly doped layers adjacent to cell, highly doped adjacent to reflector). However, in this case the layer sheet resistance will be higher than when exactly the same layers are deposited with the highly doped layer first.

Technically B₂H₆ (boron dopant) is available as a gas mixture of 2% B₂H₆ in hydrogen. Within the context of this disclosure the doping ratios are based on said technical gas mixture and the term “boron” or B₂H₆ means said technical gas mixture.

### FURTHER ADVANTAGES OF THE INVENTION

In general highly doped ZnO layers have a lower refractive index than lowly doped or intrinsic layers. Adding a highly doped ZnO layer 72 directly on a glass substrate 71 will result in a smoother increase of the refractive index from the glass to the ZnO. Thus, reflection of incoming light at the Glass/ZnO interface will be reduced and more light will be available to the PV modules.

Additionally, an enhanced EIL process allows a safe removal of all material deposited near the substrate edge. Even material accidentally deposited on the front glass surface is removed.

Although the invention has been described in terms of specific embodiments, it is not to be construed as being limited to such, rather it encompasses all variations falling within the scope of the appended claims.

### LIST OF REFERENCE SIGNS

41—Substrate

42—Front electrode

43—Bottom cell

44—p-doped Si layer (p pc-Si:H)

45—i-layer pc-Si:H

46—n-doped Si layer (n a-Si:H/n pc-Si:H)

47—Back electrode

48—Back reflector

50—Thin-film solar cell

51—Top cell

52—p-doped Si layer (p a-Si:H/p pc-Si:H)

53—i-layer a-Si:H

54—n-doped Si layer (n a-Si:H/n pc-Si:H)

61—Solar panel

62—Active area

63—Cells

64—Edge area

71—Substrate

72—Seed layer/higher-boron-doped layer

73—Bulk ZnO layer/lower-boron-doped layer

74, 74a, 74b, 74c, 74d—Hi-Doping layer/higer-boron-doped layer

75, 75a, 75b, 75c, 75d —Low Doping layer/lower-boron-doped layer

76—Interlayer

1. An electrode for a photoelectric conversion device comprising:
at least one basic layer sequence having a varying boron dopant concentration;
said basic layer sequence comprising a thinner transparent conductive zinc oxide higher-boron-doped layer and a thicker transparent conductive zinc oxide lower-boron-doped layer;
wherein the doping density through each individual conductive zinc oxide layer is substantially constant.

2. An electrode according to claim 1, wherein said electrode comprises a plurality of said basic layer sequences.

3. An electrode according to claim 1, further comprising a substrate, wherein the electrode is a front electrode and is arranged on the substrate, said substrate comprising glass.

4. An electrode according to claim 3, further including an interlayer disposed between the at least one basic layer sequence and the substrate.

5. An electrode according to claim 3, wherein the basic layer sequence is arranged in direct and intimate contact with said substrate.

6. An electrode according to claim 1, wherein the electrode is a back electrode and is arranged on an n-doped silicon layer.

7. An electrode according to claim 6, further including an interlayer disposed between the at least one basic layer sequence and the n-doped silicon layer.

8. An electrode according to claim 6, wherein the basic layer sequence is arranged in direct and intimate contact with the n-doped silicon layer.

9. An electrode according to claim 1, wherein the thinner transparent conductive zinc oxide higher-boron-doped layer is arranged directly adjacent to a substrate or to an n-doped silicon layer or to an interlayer between the basic layer and a substrate.

10. An electrode according to claim 4, wherein a doping concentration of the interlayer is lower than that of the thinner transparent conductive zinc oxide higher-born-doped layer.

11. A method for manufacturing an electrode for a photoelectric conversion device comprising:
depositing on a substrate or on an n-doped silicon layer at least one basic layer sequence having a varying boron dopant concentration;
wherein said basic layer sequence comprises a thinner transparent conductive zinc oxide higher-boron-doped layer and a thicker transparent conductive zinc oxide lower-boron-doped layer; and
wherein said thicker transparent conductive zinc oxide lower-boron-doped layer is intentionally doped.

12. A method according to claim 11, further comprising depositing an interlayer such that it is disposed between the substrate or the n-doped silicon layer and the at least one basic layer sequence.

13. A method according to claim 11, wherein a plurality of basic layer sequences are deposited on the substrate or on the n-doped silicon layer.

14. A method according to claim 11, wherein the basic layer sequence is deposited according to the following steps:
depositing on the substrate or the n-doped silicon layer a first transparent conductive zinc oxide layer;
depositing on said first transparent conductive zinc oxide layer a second transparent conductive zinc oxide layer,
wherein the first transparent conductive zinc oxide layer is one of the thinner transparent conductive zinc oxide higher-boron-doped layer and the thicker transparent conductive zinc oxide lower-boron-doped layer, and
wherein the second conductive zinc oxide layer is the other of the thinner transparent conductive zinc oxide higher-boron-doped layer and the thicker transparent conductive zinc oxide lower-boron-doped layer.

15. A method according to claim 11, wherein the electrode is deposited according to the following steps:
depositing an interlayer on the substrate or the n-doped silicon layer,
depositing on the interlayer a first transparent conductive zinc oxide layer,
depositing on said first transparent conductive zinc oxide layer a second transparent conductive zinc oxide layer;
wherein the first conductive zinc oxide layer is one of the thinner transparent conductive zinc oxide higher-boron-doped layer and the thicker transparent conductive zinc oxide lower-boron-doped layer, and the second transparent conductive zinc oxide layer is the other of the thinner transparent conductive zinc oxide higher-boron-doped layer and the thicker transparent conductive zinc oxide lower-boron-doped layer.

16. A method according to claim 15, wherein the first transparent conductive zinc oxide layer is the thinner transparent conductive zinc oxide higher-boron-doped layer and the second transparent conductive zinc oxide layer is the thicker transparent conductive zinc oxide lower-boron-doped layer.

17. A method according to claim 11, wherein the said layers at least one basic layer sequence is deposited by a vacuum processing method including at least one of Chemical Vapor Deposition, Low Pressure Chemical Vapor Deposition, Plasma Enhanced Chemical Vapor Deposition or Physical Vapor Deposition.

18. A method according to claim 17, wherein the thinner transparent conductive zinc oxide higher-boron-doped layer is deposited under conditions of a first diborane/diethyl zinc ratio of 0.1-1.

19. A method according to claim 18, wherein the thicker transparent conductive zinc oxide lower-boron-doped layer is deposited under conditions of a second diborane/diethyl zinc ratio of 0.01-0.2.

20. A method according to claim 19, wherein a ratio of the first diborane/diethyl zinc ratio to the second diborane/diethyl zinc ratio is between 2 and 60.

21. A method according to claim 17, wherein the transparent conductive zinc oxide layers are deposited under conditions of a H2O/diethyl zinc ratio of 0.8 to 1.5.

22. A method according to claim 17, wherein the temperature of the substrate during deposition is in a range of 150-220° C.

23. A method according to claim 13, further comprising the steps of depositing at least one further first transparent conductive zinc oxide layer and at least one further second transparent conductive zinc oxide layer so as to form a plurality of basic layer structures.

24. A method according to claim 1, wherein the thinner transparent conductive zinc oxide higher-boron-doped layer and the thicker transparent conductive zinc oxide lower-boron-doped layer are deposited in two separate, discrete processing steps.

25. A method according to claim 19, wherein the thinner transparent conductive zinc oxide higher-boron-doped layer and the thicker transparent conductive zinc oxide lower-boron-doped layer are deposited sequentially by varying the diborane/diethyl zinc ratio from the first diborane/diethyl zinc ratio to the second diborane/diethyl zinc ratio or from the second diborane/diethyl zinc ratio to the first diborane/diethyl zinc ratio over a time period of 30 seconds or less.

26. A method according to claim 12, wherein the doping concentration of the interlayer is lower than that of the thinner transparent conductive zinc oxide higher-born-doped layer.

27. A method according to claim 17, wherein the thinner transparent zinc oxide higher-boron-doped layer is deposited under conditions of a first diborane/diethyl zinc ratio of 0.2-0.55;
wherein the thicker transparent zinc oxide lower-boron-doped layer is deposited under conditions of a second diborane/diethyl zinc ratio of 0.02-0.1; and
wherein a ratio of the first diborane/diethyl zinc ratio to the second diborane/diethyl zinc ratio is between 7 and 10.
